(19) United States
(12) Patent Application Publication
(10) Pub. No.: US 2006/0259893 A1
(43) Pub. Date: Nov. 16, 2006

(54) Photomask, photomask set, photomask design method, and photomask set design method

(75) Inventor: Masashi Fujimoto, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/116,350

(22) Filed: Apr. 28, 2005

(51) Int. Cl. G03F 1/00; G06F 17/50

(52) U.S. Cl. 716/19; 430/5

(57) ABSTRACT

There is provided a photomask in which influences of line-end shortening and corner rounding of a gate pattern are suppressed. A block having a plurality of gate electrodes are formed in the photomask, all of the longitudinal directions of the plurality of gate electrodes in each block are equal to each other, and the patterns of the plurality of gate electrodes are extended to an end of the block in the longitudinal direction.

This application is based on Japanese Patent application NO. 2004-005559, the content of which is incorporated hereinto by reference.

### BACKGROUND OF THE INVENTION

1. Field of the Invention

The present invention relates to a photomask, a photomask set, and methods of designing the photomask and photomask set which are used to form a gate pattern on a photoresist in an exposing step among the steps of manufacturing a semiconductor integrated circuit

2. Description of the Related Art

With increases in integration density and processing speed of a device, a micropattern which is considerably smaller than an exposure wavelength is required to be formed in a lithography step, especially in the step of forming a gate to form a gate electrode of a transistor.

For example, in a 130-nm node device and a 90-nm node device, a resist pattern having almost the same dimensions as those needs to be formed by KrF exposure having a light source wavelength of 248 nm or ArF exposure having a light source wavelength of 193 nm.

FIG. 10 is a graph showing an optical contrast of 100-nm isolated lines in the KrF exposure and the ArF exposure. In this graph, the optical contrast is defined by [(light intensity at pattern center)−(light intensity at pattern edge)]÷(light intensity at pattern edge). In order to resolve a pattern in a preferable shape, it is considered that an optical contrast of about 0.5 or more is necessary. As is apparent from FIG. 10, it is very difficult to form a 100 nm pattern which is about half the wavelength or less by a general exposing method. For this reason, various super-resolving techniques are examined.

Of these super-resolving techniques, a Levenson phase shift mask is considered as the most promised technique in the formation of a pattern which is of about half the wavelength or less because the Levenson phase shift mask has an effect of increasing, especially, an optical contrast or resolving power (for example, refer to Laid-open patent publication H05-313342). The Levenson phase shift mask is the method in which a high resolving power can be obtained by utilizing complete cancellation of positive and negative photoelectric fields (0−π) due to an arrangement of a shifter such that phases of transmitted light of adjacent mask openings are inverted. A part of the shifter which inverts a phase is formed such that the thickness of a mask is controlled by etching of a substrate surface of the mask to invert the phase of the transmitted light in manufacturing a photomask.

A conventional gate pattern will be described below.

FIG. 11 is a layout diagram showing an arrangement example of a plurality of transistors. FIG. 11 shows a layout of transistors in a block serving as a region in which a plurality of transistors are formed. The block is a basic logic circuit block such as a NOT device and NAND device, a basic logic circuit block obtained by combining a plurality of logic circuit blocks, or a memory circuit block in which a memory device is formed.

In the block shown in FIG. 11, in a transistor 200, a source electrode and a drain electrode are formed on a diffusion layer 230 of a semiconductor substrate. A part in an active region of the semiconductor substrate of the gate pattern 211 serves as a gate electrode 211 of the transistor.

As shown in FIG. 11, the gate electrode 211 is arranged such that the longitudinal direction thereof is equal to the horizontal direction of FIG. 11. Gate electrodes in a gate pattern 212a and a gate pattern 212b are also arranged such that the longitudinal directions thereof are equal to the horizontal direction of FIG. 11. On the other hand, gate electrodes in a gate pattern 216 and a gate pattern 218 are arranged such that the longitudinal directions thereof are equal to the vertical direction of FIG. 11. In this manner, the longitudinal directions of the gate electrodes are not fixed to one direction in the same block.

The arrangement in which the longitudinal directions of gate electrodes are fixed to one direction in the block is described in Laid-open patent publication NO. 2000-112114.

FIG. 12 is a layout diagram in a Levenson phase shift mask of the gate pattern shown in FIG. 11.

As shown in FIG. 12, in the Levenson phase shift mask, a part “0” which directly transmits light and a part “π” serving as an inverting shifter to invert a phase by 180° to transmit light are arranged. In the following description, the part “0” which does not invert a phase and the part “π” which inverts a phase are referred to as phase shifters. In an exposing step, a gate pattern is formed on a resist by using the Levenson phase shift mask shown in FIG. 12. However, with this process alone, a large number of unnecessary (0−π) phase edges are generated around the phase shifters, which results in forming an unnecessary resist pattern. Therefore, by using a trim mask to remove the unnecessary resist pattern, the second exposure is performed. Light is irradiated on a part corresponding to an opening 240 in FIG. 13. In this manner, the unnecessary phase edges can be erased.

As described above, in order to form a gate pattern by using the Levenson phase shift mask, two types of photomask data, i.e., the Levenson phase shift mask and the trim mask need to be formed, and the two types of photomasks need to be manufactured.

In the conventional method using the Levenson phase shift mask, the following problems are mainly posed.

In the first place, arrangements of phase shifters are contradicted. A conventional circuit layout is not designed in careful consideration of the arrangements of phase shifters. For example, the longitudinal directions of gate electrodes of transistors are vertically and horizontally set at random, which makes it very difficult to alternately arrange “0” and “π” of the phase shifters. As shown in FIG. 14, there generates a portion where “0” and “0” (or “π” and “π”) are adjacent to each other on both sides of a micropattern in the entire circuit pattern. A resolving power is considerably deteriorated in this portion, thus causing disconnection or short circuit of a gate pattern.

The conventional method is considerably affected by the optical proximity effect. Since the Levenson phase shift mask uses an imaging method positively using optical interference, the Levenson phase shift mask is considerably affected by the proximity effect caused by the optical interference in principle. Pattern density dependency, shifter width dependency, line-end shortening, corner rounding, and the like of a pattern dimension are likely to occur due to the influence of the proximity effect. In a conventional random layout, since there are a large number of portions having pitches and shifter widths which change along the line, dimensions and shapes of the portions largely change. As a matter of course, although the dimensions and the shapes are corrected by OPC (Optical Proximity Correction), the original dimensions and shapes largely vary. For this reason, correction precision is poor (post-correction residual is large), and in some cases, the line-end shortening and the corner rounding which cause defect in electric property may be so large to be corrected.

Furthermore, the method is considerably affected by aberration. Since the effect of the aberration of a projection lens changes depending on a pattern direction, the dimensions of vertical and horizontal transistor gates are different from each other in a conventional random layout. This causes a defect in electric property.

The affect of the optical proximity effect or the aberration also occurs when a mask except for the Levenson phase shift mask, for example, a halftone mask, a binary mask, or the like is used.

### SUMMARY OF THE INVENTION

The present invention has been made to solve a problem involved in the conventional technique, and has as its object to provide a photomask, a photomask set, and methods of designing the same which suppress influences of line-end shortening and corner rounding of a gate pattern.

According to the present invention, there is provided a photomask in which a block having a plurality of gate electrodes are formed, wherein

longitudinal directions of the plurality of gate electrodes in each block are equal to each other, and

patterns of the plurality of gate electrodes are extended to an end of the block in the longitudinal direction.

According to the present invention, since the longitudinal directions of the gate electrodes are set to a predetermined direction, a variation in aberration caused when the longitudinal directions of the gate electrodes are set at random can be suppressed, and a variation in dimension of the gate pattern caused by the aberration can be reduced.

According to the present invention, since the longitudinal direction of the gate electrodes in each block are set to a predetermined direction, a variation in aberration caused when the longitudinal directions of the gate electrodes in each block are set at random can be suppressed, and a variation in dimension of the gate pattern caused by aberration is reduced.

Furthermore, according to the present invention, since resist patterns having gate electrodes extended to an end of a block are formed in an exposing step, line-end shortening and corner rounding of the gate pattern including the gate electrodes are suppressed.

According to the present invention, there is provided a photomask set including: a first photomask in which a block having a plurality of gate electrodes are formed, all of the longitudinal directions of the plurality of gate electrodes in each block are equal to each other, and patterns of the plurality of gate electrodes are extended to an end of the block in the longitudinal direction; and a second photomask for removing an unnecessary part of the patterns of the gate electrodes formed on a resist by the first photomask.

According to the present invention, in an exposing step, since resist patterns having gate electrodes extended to an end of a block is formed by the first photomask, and since an unnecessary part is removed from the resist patterns by the second photomask, line-end shortening and corner rounding of the gate patterns including the gate electrodes are suppressed.

Furthermore, in the photomask set according to the present invention, the first photomask may be a phase shift mask.

According to the present invention, when phase shifters are arranged on a photomask in which patterns having gate electrodes extended to an end of a block are formed, phase shifters of “0” and “π” are alternately arranged. For this reason, the arrangements of the phase shifters are prevented from being contradicted, and deterioration of a resolving power caused by the contradicted arrangements of the phase shifters, and disconnection and short circuit of the gate pattern are suppressed.

According to the present invention, there is provided a method of designing a photomask which causes a computer to execute a process of arranging a plurality of patterns of gate electrodes of transistors, wherein, when positions of the transistors are input, the gate electrodes are arranged such that all of the longitudinal directions of the gate electrodes are equal to each other depending on the positions of the transistors.

According to the present invention, there is provided the method of designing a photomask which causes a computer to execute a process of arranging a plurality of gate electrodes on a photomask on which a block for arranging the plurality of gate electrodes are formed, wherein, when positions of a transistors are input for each of the blocks, the gate electrodes are arranged such that all of the longitudinal directions of the gate electrodes are equal to each other depending on the positions of the transistors for each of the blocks.

In the method of designing a photomask according to the present invention, a first photomask in which patterns of the plurality of gate electrodes are extended to an end of the block in the longitudinal directions may be formed.

According to the present invention, there is provided a method of designing a photomask set, wherein a first photomask is formed by using the method of designing a photomask, and when an unnecessary part of the patterns extended in the first photomask is input, a second photomask having an opening formed in the unnecessary part is formed.

Furthermore, in the method of designing a photomask set according to the present invention, phase shifters may be arranged between patterns in which the gate electrodes are extended in the first photomask.

In the photomask, the photomask set, and the method of designing the same according to the present invention, an influence of aberration is suppressed, and a variation in dimension caused by aberration is reduced.

In addition, influences of line-end shortening and corner rounding of the gate pattern can be suppressed.

Furthermore, if the photomask is a phase shift mask, deterioration of a resolving power caused by contradicted arrangements of phase shifters can be prevented, and disconnection and short circuit of the gate pattern can be suppressed.

### BRIEF DESCRIPTION OF THE DRAWINGS

The above and other objects, advantages and features of the present invention will be more apparent from the following description taken in conjunction with the accompanying drawings, in which:

FIG. 1 is a layout diagram showing a configuration example of a transistor pattern of a photomask according to the present invention;

FIG. 2 is a flow chart showing a method of designing a photomask according to the present invention;

FIG. 3 is a layout diagram showing a configuration example of a gate pattern of the photomask according to the present invention;

FIG. 4 is a layout diagram showing a configuration example of a phase shift pattern of the photomask according to the present invention;

FIG. 5 is a layout diagram showing a case in which gate patterns overlap;

FIG. 6 is a layout diagram showing a case in which a gate pattern is arranged at a pitch smaller than a marginal resolving power;

FIG. 7 is a layout diagram showing a case in which virtual lines are drawn;

FIG. 8 is a layout diagram showing a configuration example of a trim pattern of the photomask according to the present invention;

FIG. 9 is a diagram showing a configuration example of transistor patterns in various blocks in an IC chip;

FIG. 10 is a graph showing a relationship between an optical contrast and NA of a lens;

FIG. 11 is a layout diagram showing a configuration example of a transistor pattern of a conventional photomask;

FIG. 12 is a layout diagram showing a configuration example of a phase shift pattern of the conventional photomask;

FIG. 13 is a layout diagram showing a configuration example of a trim pattern of the conventional photomask; and

FIG. 14 is a layout diagram showing an example of a problem in a phase shift pattern of the conventional photomask.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

In a photomask according to the present invention, longitudinal directions of gate electrodes of transistors are set to a specific direction.

A gate pattern formed by using the photomask according to the present invention will be described below.

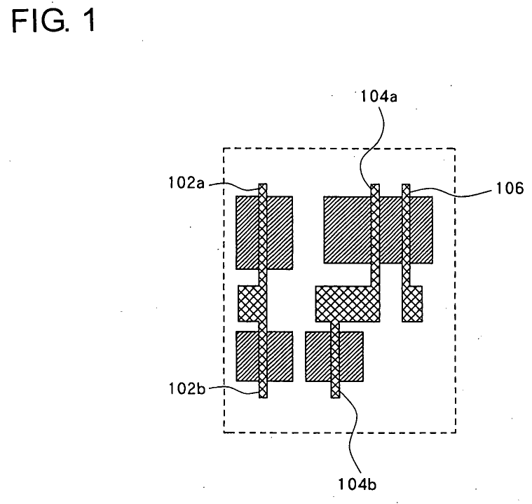

FIG. 1 is a layout diagram showing a configuration example of transistors formed by the photomask set according to the present invention. In FIG. 1, a plurality of transistors are arranged in a block.

In FIG. 1, five transistors are arranged in the block. As shown in FIG. 1, longitudinal directions of gate electrodes of gate patterns 102a, 102b, 104a, 104b, and 106 correspond to the vertical direction of FIG. 1.

A method of designing a photomask set of the gate pattern shown in FIG. 1 will be described below.

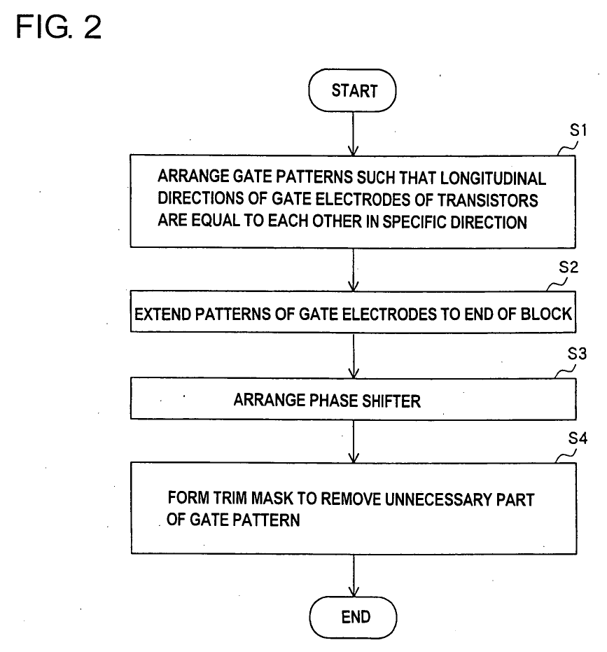

FIG. 2 is a flowchart showing the method of designing a photomask set.

As step S1, as shown in FIG. 1, a gate pattern is laid out such that the longitudinal directions of the gate electrodes of the transistors are set to a specific direction. In this case, the specific direction is the vertical direction of FIG. 1. The gate pattern is preferably laid out such that the longitudinal directions of the gate electrodes of the transistors are set to be equal to each other in the specific direction in a host circuit block obtained by combining the transistors. For example, the longitudinal directions of the gate electrodes are preferably set to be equal to each other in a logic circuit block, and the longitudinal directions of all the gate electrodes are also set to be equal to each other in a basic logic circuit block obtained by combining a plurality of the logic circuit blocks. Furthermore, the pattern is more preferably laid out such that longitudinal directions of gate electrodes of transistors can be set to be equal to each other in a specific direction in an entire IC (Integrated Circuit) chip.

In this manner, the longitudinal directions of the gate electrodes of the transistors are limited to a specific direction to make it extremely easy to arrange shifters on a phase shift mask, as will be described later. In addition, a variation in aberration caused when the longitudinal directions of the gate electrodes are set at random is suppressed, and a variation in dimension of a gate pattern caused by the aberration is reduced.

Although the specific direction is set to the vertical direction of FIG. 1, the direction may be the horizontal direction or a direction inclined by 45 degrees from the vertical direction.

A wiring portion which does not serve as the gate electrode of the transistor shown in FIG. 1 may exist in either the vertical direction or the horizontal direction. However, when the wiring portion exists in a direction which is not the “specific direction”, an effect obtained by a phase shift mask, to be described later, is not utilized. For this reason, care should be taken because disconnection or the like occurs unless the line width and the pitch are set to be equal to or larger than the marginal resolving power of conventional exposure.

Since an aberration (influence of image height) in sagittal imaging is generally smaller than an aberration in meridional imaging, when a line is imaged by a scan exposing device, a line in almost an scan direction is imaged by the meridional imaging, and a line in a direction vertical to the scan direction (non-scan direction) is imaged by the sagittal imaging. For this reason, the gate patterns of the transistors are preferably laid out in the non-scan direction.

As step S2 shown in FIG. 2, the patterns of the gate electrodes of the transistors are extended from one end of a block to the other end of the block.

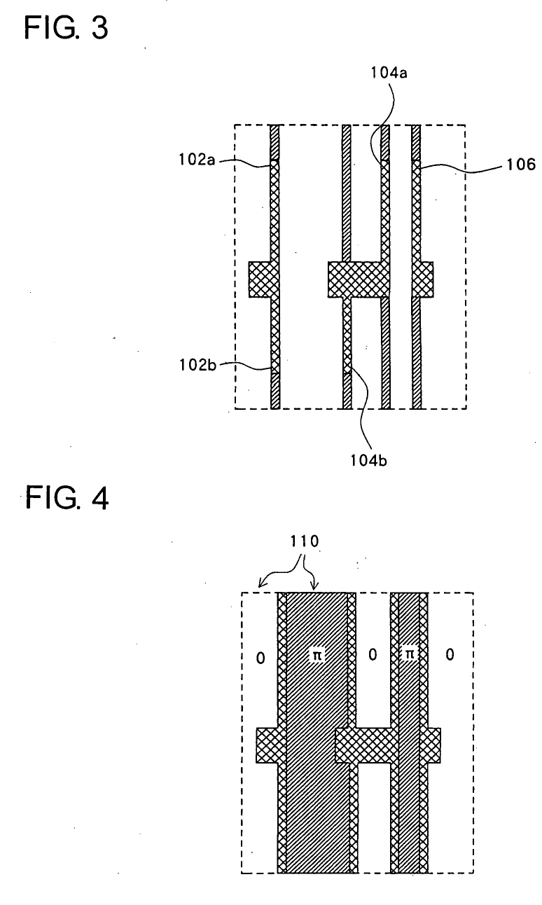

FIG. 3 is a layout diagram showing a case in which patterns of gate electrodes are extended to an end of a block.

As shown in FIG. 3, the limited direction of the patterns of the gate electrodes in step S1 is extended to an end (boundary) of the block in the vertical direction of FIG. 3. In this manner, when the dimension in a direction vertical to the longitudinal direction of the gate electrode is called a “gate length”, in a gate pattern 102a, a pattern extended to an end of the block is formed on the upper side in FIG. 3 while keeping the gate length constant. In a gate pattern 102b, a pattern extended to an end of the block is formed on the lower side in FIG. 3 while keeping the gate length constant. In gate patterns 104a, 104b, and 106, patterns extended to an end of a block are formed on both upper and lower sides in FIG. 3 while keeping gate lengths constant.

With this process, since lines obtained by extending the patterns of the gate electrodes are formed while keeping the gate lengths constant, a phenomenon in which a distance to an adjacent line in the middle of a line or a width of a phase shift varies can be minimized. Therefore, an influence of an optical proximity effect can be considerably reduced, and OPC precision can be considerably improved.

The pattern of the gate electrode of the transistor is extended to a block end so as to avoid influences of line-end shortening and corner rounding of a phase shifter, i.e., the problems of the Levenson phase shift mask. Therefore, a load for forming a complex shape such as a serif or a hat by OPC can be reduced.

With respect to the process, processing contents are written in advance in a computer readable program so as to cause a CAD (Computer Aided Design) to execute the process.

Next, a phase shifter 110 is arranged as step S3 shown in FIG. 2. Steps S1 to S3 are included in a method of designing a first photomask. The method is added with the formation of a second photomask in step S4, to be described later, to design a photomask set.

FIG. 4 is a layout diagram in which phase shifters are arranged.

With the process in step S2, the arrangements of the phase shifters 110 may be considered in one dimension in a direction (horizontal direction of FIG. 3) vertical to the longitudinal direction of the gate electrode of the transistor. Referring to FIG. 3, since the longitudinal directions of the gate electrodes are set to be equal to each other in the vertical direction of FIG. 3 in step S1, phases of the gate patterns are constant. For this reason, as shown in FIG. 4, the phase shifters 110 of “0” and “π” may be alternately arranged from one end in the horizontal direction. This means that phase contradiction can be completely avoided by the method of the present invention. In addition, since only one dimension may be considered, the phase shifters can be easily arranged to reduce work for design. This process can be also executed by a CAD.

Arrangements of gate patterns which cannot be employed will be described below.

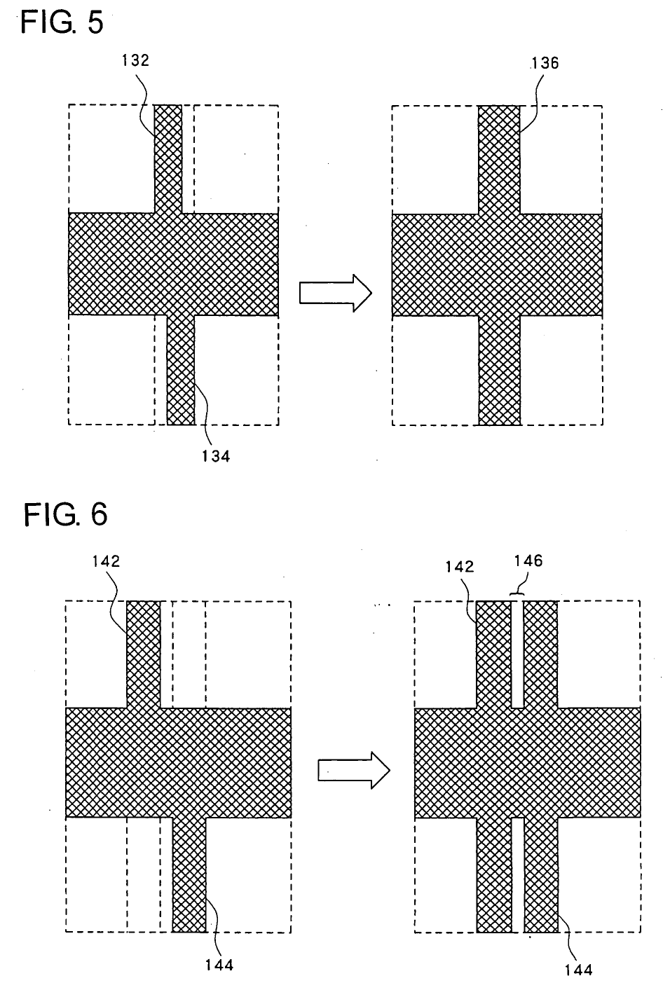

FIGS. 5 and 6 are layout diagrams showing a case where the present invention cannot be applied.

FIG. 5 shows a case in which a gate pattern 132 and a gate pattern 134 overlap. In this case, the gate length of a gate pattern 136 obtained by overlapping the gate pattern 132 and the gate pattern 134 is formed to have a width larger than a target size. For this reason, a transistor having a gate electrode with a gate length larger than the target size is formed, thus designed operation characteristics cannot be obtained.

FIG. 6 shows a case in which a slit 146 smaller than a marginal resolving power is formed between the gate pattern 142 and the gate pattern 144. A pitch is smaller than a marginal resolving power or a design rule.

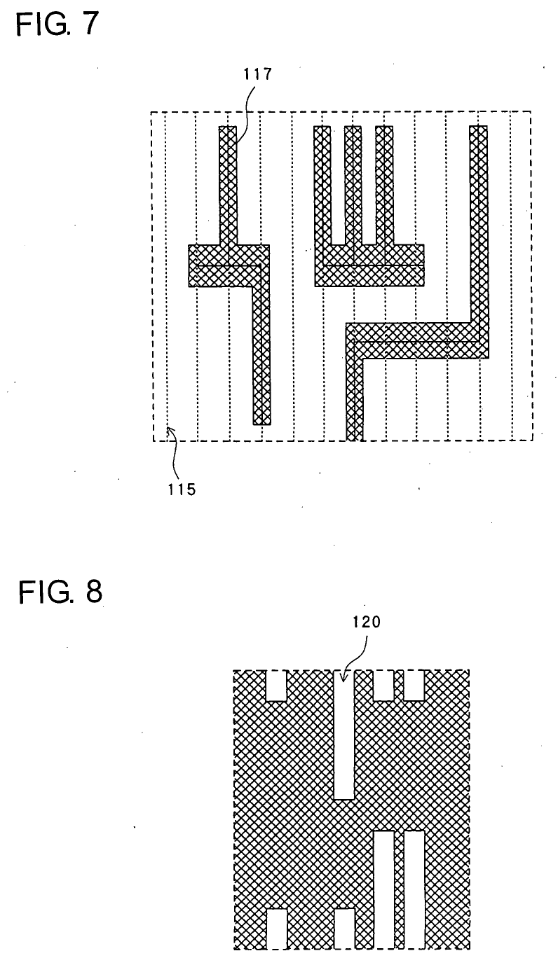

In this manner, in order to perform the processes in steps S2 and S3, the layouts of the gate patterns are preferably not as those in FIG. 5 and FIG. 6. As one of the most effective methods, as shown in FIG. 7, virtual lines 115 are arranged in advance at equal intervals which are minimum pitches, and gate patterns 117 are laid out on the virtual lines 115. In this case, since the longitudinal directions of the gate electrodes of the transistors are limited to one direction, it is not necessary to arrange the gate electrodes in the form of a two-dimensional grating, and it is satisfactory to arrange the virtual lines 115 one-dimensionally at equal intervals. The virtual lines 115 are virtually displayed at the design phase and are not formed on the photomask.

When an operator operates a CAD to design a photomask, the virtual lines 115 shown in FIG. 7 may be displayed on a computer. In this case, when the operator inputs the position of a transistor to the computer, the computer arranges a gate electrode depending on the position of the transistor. At this time, since the gate electrode is arranged to overlap the virtual lines 115, the longitudinal direction of the gate electrode is equal to the direction of the virtual line 115.

As step S4 shown in FIG. 2, a trim mask serving as a second photomask to remove an unnecessary part is designed.

FIG. 8 is a pattern diagram in a block on the trim mask.

Since the extended part of the gate pattern obtained in the process of step S2 is an unnecessary pattern on the circuit, as shown in FIG. 8, an opening 120 to erase the extended part by exposure is formed in the trim mask. The pattern including the opening 120 serves as trim mask data.

A CAD can also be caused to design a trim mask by the following method. When an operator inputs an unnecessary part, which is the extended part of the gate pattern, to a computer, the computer forms the trim mask having an opening formed in the unnecessary part of the gate pattern as shown in FIG. 8.

In order to avoid an influence of an optical proximity effect, blocks are arranged at an interval of about 0.5 μm or more. However, when the blocks must be wired to be connected to each other, a light-shielding pattern may be formed in the trim mask.

Double exposure is performed or exposure is performed twice by using two masks, i.e., the phase shift mask and the trim mask shown in FIG. 4 and FIG. 8, respectively, manufactured as described above. Thus, the gate pattern shown in FIG. 1 can be formed at a high precision.

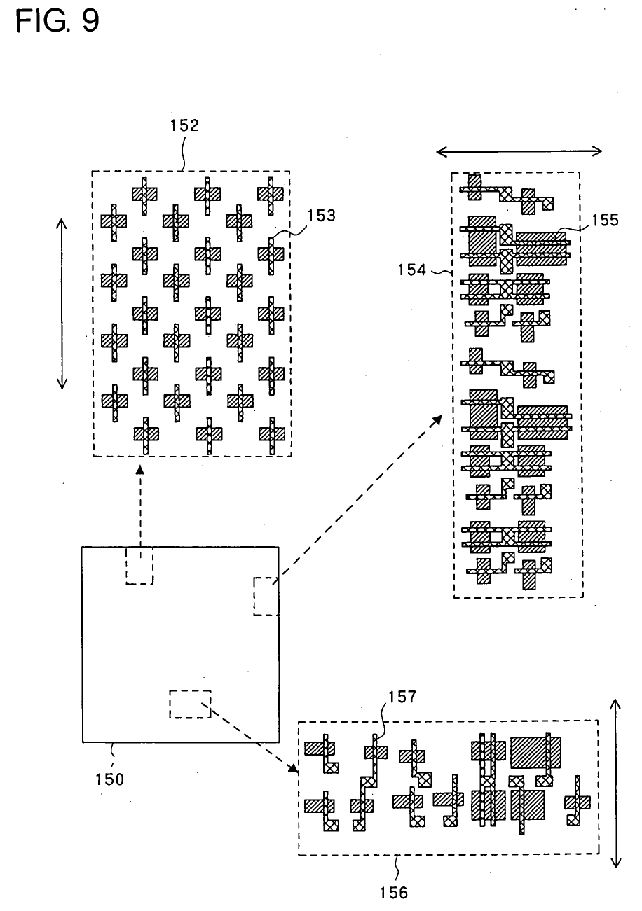

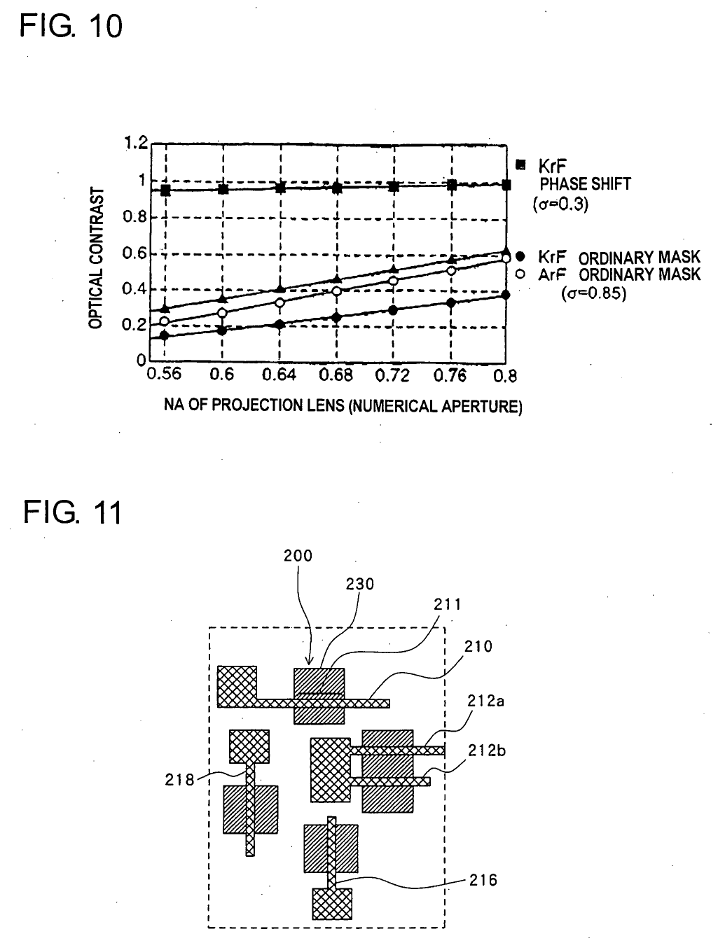

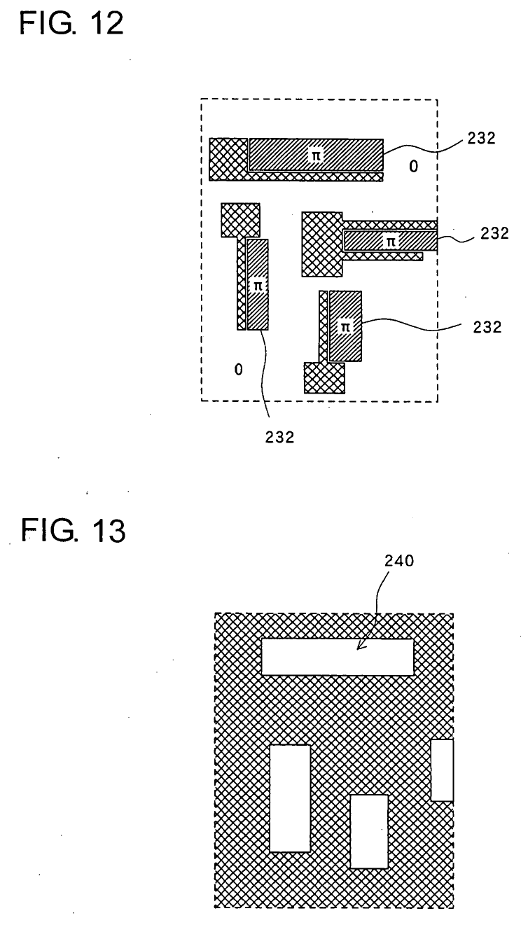

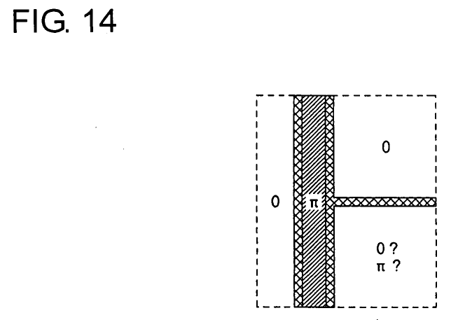

Although the above embodiment is described paying attention to one block in an IC chip, it is sufficient that the longitudinal directions of gate electrodes in each block in the IC chip are equal to each other. FIG. 9 is a diagram showing a configuration example of transistor patterns in various blocks in the IC chip. Blocks 152, 154, and 156 show blocks selected from arbitrary blocks in an IC chip 150 at random. The block may be any one of a logic circuit block, a basic logic circuit block, and a memory circuit block.

As shown in FIG. 9, in a block 152, the longitudinal directions of gate electrodes of gate patterns 153 are equal to each other in the vertical direction of FIG. 9. In a block 156, the longitudinal directions of gate electrodes of the gate patterns 157 are equal to each other in the vertical direction of FIG. 9. In a block 154, the longitudinal directions of gate patterns 155 are equal to each other in the horizontal direction of FIG. 9.

On the other hand, the longitudinal directions of all the gate electrodes in the IC chip may be equal to each other. In this case, variations in aberration of all the gate patterns in the IC chip are suppressed, and variations in dimension caused by the aberration are reduced.

The embodiment has been described on the assumption that a Levenson phase shift mask is used as a phase shift mask. However, the present invention can be applied to an ordinary photomask and halftone mask except for a process of arranging phase shifters. For this reason, with respect to the ordinary photomask and halftone mask, an advantage of reducing an influence of aberration by limiting directions to a specific direction, an advantage of being capable of minimizing a change in pitch in the middle of a line, an advantage of being capable of minimizing influences of line-end shortening and corner rounding, and the like can also be obtained as in a Levenson phase shift.

It is apparent that the present invention is not limited to the above embodiment, that may be modified and changed without departing from the scope and spirit of the invention.

1. A photomask in which a block having a plurality of gate electrodes are formed,
wherein longitudinal directions of said plurality of gate electrodes in said blocks are equal to each other, and
patterns of said plurality of gate electrodes are extended to an end of said block in said longitudinal direction.

2. A photomask set comprising:
a first photomask in which a block having a plurality of gate electrodes are formed, all of the longitudinal directions of said plurality of gate electrodes in said block are equal to each other, and patterns of said plurality of gate electrodes are extended to an end of said block in said longitudinal direction; and
a second photomask which removes an unnecessary part of the patterns of the gate electrodes formed on a resist by said first photomask.

3. The photomask set according to claim 2,
wherein said first photomask is a phase shift mask.

4. A method of designing a photomask which causes a computer to execute a process of arranging a plurality of patterns of gate electrodes of transistors,
wherein, when the positions of said transistors are input, the gate electrodes are arranged such that all of the longitudinal directions of said gate electrodes are equal to each other depending on the positions of said transistors.

5. A method of designing a photomask which causes a computer to execute a process of arranging a plurality of gate electrodes on a photomask on which a block for arranging the plurality of gate electrodes are formed,
wherein, when the positions of transistors are input for each of said blocks, the gate electrodes are arranged such that all of the longitudinal directions of said gate electrodes are equal to each other depending on the positions of said transistors for each of said blocks.

6. The method of designing a photomask according to claim 5,
wherein the patterns of said plurality of gate electrodes are extended to an end of said block in said longitudinal direction.

7. The method of designing a photomask according to claim 6,
wherein a first photomask is formed by, and when an unnecessary part of said patterns extended in said first photomask is input, a second photomask having an opening formed in said unnecessary part is formed.

8. The method of designing a photomask set according to claim 7,
wherein phase shifters are arranged between patterns in which said gate electrodes are extended in the first photomask.
